(19) United States
(12) Patent Application Publication
(10) Pub. No.: US 2017/0137944 A1
(43) Pub. Date: May 18, 2017

(54) PLASMA PROCESSING APPARATUS AND PLASMA PROCESSING METHOD

(71) Applicant: TOKYO ELECTRON LIMITED, Tokyo (JP)

(72) Inventors: Shinji KUBOTA, Miyagi (JP); Yusuke ICHIKAWA, Miyagi (JP)

(73) Assignee: TOKYO ELECTRON LIMITED, Tokyo (JP)

(21) Appl. No.: 15/322,635

(22) PCT Filed: Jun. 23, 2015
(86) PCT No.: PCT/JP2015/068064

§ 371 Date: Dec. 28, 2016

(30) Foreign Application Priority Data
Jul. 3, 2014 (JP) 2014-138126

(51) Int. Cl. C23C 16/511; H01J 37/32; H01L 21/3065; H01L 21/67; C23C 16/455; C23C 16/52

(52) U.S. Cl. CPC C23C 16/511; C23C 16/455; C23C 16/52; H01L 21/3065; H01L 21/67069; H01J 37/32715; H01J 37/3244; H01J 37/32201; H01J 37/32311; H01J 2237/332

(57) ABSTRACT

This plasma processing apparatus is provided with a processing container, a placing table, a gas supply mechanism, a plasma generating mechanism, and an adjustment unit. The placing table is provided in the processing container, and a subject to be processed is placed on the placing table. The gas supply mechanism supplies a processing gas to the inside of the processing container, said processing gas being to be used for the purpose of plasma reaction. The plasma generating mechanism includes a microwave oscillator, and brings the processing gas supplied to the inside of the processing container into the plasma state using microwaves oscillated by means of the microwave oscillator. In the cases of performing a plurality of steps for plasma-processing the subject, the adjustment unit adjusts, at timing of switching the steps, the frequencies of the microwaves to be oscillated by means of the microwave oscillator to target frequencies predetermined for respective steps.

### TECHNICAL FIELD

Various aspects and embodiments of the present disclosure relate to a plasma processing apparatus and a plasma processing method.

### BACKGROUND

A plasma processing apparatus exists in which a processing gas is brought into a plasma state using a microwave oscillator oscillating microwaves within a processing container. As the microwave oscillator, for example, an inexpensive magnetron capable of oscillating high-output microwaves or a phase locked loop (PLL) oscillator capable of oscillating microwaves where a reference frequency and a phase are synchronized with each other is used.

However, in the plasma processing apparatus using the microwave oscillator, the frequency of the microwaves by the microwave oscillator (hereinafter, appropriately referred to as an “oscillation frequency”) may vary from a desired target frequency due to various factors. For example, since the magnetron oscillator is a machined product, the oscillation frequency may vary from a desired frequency due to a machine error among a plurality of magnetron oscillators. Further, since the magnetron oscillator has a frequency dependency on an output power, the oscillation frequency may vary from the desired frequency due to the intensity of the output power.

Thus, various technologies for fixing the oscillation frequency to a desired frequency are being reviewed. For example, there is a technology that fix the oscillation frequency to the frequency of the reference signal by injecting a reference signal having a frequency close to the oscillation frequency into the magnetron oscillator.

### PRIOR ART DOCUMENT

### Patent Document

Patent Document 1: Japanese Patent Laid-Open Publication No. 2002-043848

Patent Document 2: Japanese Patent Laid-Open Publication No. 2002-294460

Patent Document 3: Japanese Patent Laid-Open Publication No. 2006-287817

Patent Document 4: Japanese Patent Laid-Open Publication No. 2007-228219

### DISCLOSURE OF THE INVENTION

### Problems to be Solved

However, when each of a plurality of steps for plasma-processing a subject to be processed (“workpiece”) is performed, the above-described conventional technologies do not consider adjusting the frequency of the microwaves to an optimum frequency for each of the steps.

For example, it is taken into account a case where a plasma-processing step for plasma-processing a workpiece with plasma of a processing gas is performed after an igniting step for bringing the processing gas into a plasma state using microwaves is performed. In this case, in the conventional technologies, the frequency of the microwaves is fixed at almost the same frequency during both the igniting step and the plasma-processing step. The frequency is not necessarily suitable for each of the igniting step and the plasma-processing step. Thus, in the conventional technologies, plasma is ignited under a separate condition that facilitates the ignition of plasma, which is different from an optimum condition of the process, and thereafter, the changing of a condition (e.g., a pressure) is performed in the state where plasma is ignited. Accordingly, there is a problem of, for example, an influence on an etched shape, a deterioration of uniformity, or a loss of etching time in, for example, a dry etching of the igniting step. Further, in the conventional plasma apparatus, a discharge is not ignited as long as a pressure is not relatively high due to a high microwave power. Further, ranges for a gas condition and a process condition that enable the ignition of a discharge are very narrow. In the process condition, there are problems in that a stability of the discharge largely varies depending on types of a gas, and since a range for a condition under which plasma becomes stable is very narrow, plasma becomes unstable when the condition is slightly changed. Further, there is a problem in that, even when apparatuses are discharged under the same condition, plasma becomes unstable in each apparatus, the discharge is not ignited, or the uniformity of plasma is unexpectedly destroyed.

### Means to Solve the Problems

A plasma processing apparatus disclosed herein, in an aspect, includes a processing container, a placing table, a gas supply mechanism, a plasma generating mechanism, and an adjustment unit. The placing table is provided inside the processing container and places a workpiece thereon. The gas supply mechanism supplies a processing gas used for a plasma reaction to the inside of the processing container. The plasma generating mechanism includes a microwave oscillator and brings the processing gas supplied to the inside of the processing container into a plasma state using microwaves oscillated by the microwave oscillator. When each of a plurality of steps for plasma-processing the workpiece is performed, the adjustment unit adjusts the frequency of the microwaves oscillated by the microwave oscillator to a predetermined target frequency for each of the steps at a timing when each of the plurality of steps is switched.

### Effect of the Invention

According to the aspect of the plasma processing apparatus described herein, it is possible to achieve an effect in which when each of the plurality of steps for plasma-processing a workpiece is performed, the frequency of the microwaves may be adjusted to an optimum frequency for each of the steps.

Since a frequency at which plasma is most prone to be ignited may be set in the igniting step, the ignition may be performed with a less power so that a consumption of an electrode member and a generation of particles may be suppressed.

Further, since a change of a condition is not required between the igniting step and the process step, and the process step is ended only with the change of the frequency so that the process time is largely reduced.

Further, since an optimum frequency different depending on gas types and conditions is set in the process step, the microwaves are effectively absorbed to plasma, and as a result, a plasma density is high so that the plasma becomes stable, and an in-plane uniformity of the plasma density is high so that it is possible to provide a plasma processing method in which a difference in process condition for respective apparatuses is small.

By setting a frequency avoiding a frequency region where a so-called mode jump in which the plasma state changes occurs, plasma with a large stable margin may be provided.

### BRIEF DESCRIPTION OF THE DRAWINGS

FIG. 1 is a view illustrating an exemplary processing flow of a plasma processing method according to an exemplary embodiment.

FIG. 2 is a view schematically illustrating a plasma processing apparatus according to an exemplary embodiment.

FIG. 3 is a view illustrating an exemplary configuration of a PLL oscillator in an exemplary embodiment.

FIG. 4 is a view illustrating exemplary functional blocks of a controller in an exemplary embodiment.

FIG. 5A is a view illustrating a correlation among an oscillation frequency, a power of traveling waves of microwaves, and positions of movable plates of a tuner.

FIG. 5B is a view illustrating a correlation between an oscillation frequency and a power of traveling waves of microwaves.

FIG. 6A is a view illustrating a correlation among an oscillation frequency, a power of traveling waves of microwaves, a power of reflected waves of microwaves, and positions of movable plates of a tuner.

FIG. 6B is a view illustrating a correlation among an oscillated frequency, a power of traveling waves of microwaves, a power of reflected waves of microwaves, and positions of movable plates of a tuner.

FIG. 6C is a view illustrating a correlation among an oscillated frequency, a power of traveling waves of microwaves, a power of reflected waves of microwaves, and positions of movable plates of a tuner.

FIG. 6D is a view illustrating a correlation among an oscillated frequency, a power of traveling waves of microwaves, a power of reflected waves of microwaves, and positions of movable plates of a tuner.

FIG. 7 is a view illustrating a correlation among an oscillated frequency when a power of reflected waves of microwaves becomes the lowest, a power of traveling waves of microwaves, and a pressure inside a processing container.

FIG. 8A is a view illustrating a correlation among an oscillated frequency, a light emission intensity of plasma of a specific wavelength inside a processing container, a power of traveling waves of microwaves, a power of reflected waves of microwaves, and positions of movable plates of a tuner.

FIG. 8B is a view illustrating a correlation among an oscillated frequency, a light emission intensity of plasma of a specific wavelength inside a processing container, a power of traveling waves of microwaves, a power of reflected waves of microwaves, and positions of movable plates of a tuner.

FIG. 9 is a view illustrating a correlation between an oscillated frequency and a pixel value indicating a plasma distribution.

FIG. 10 is a view illustrating a correlation among an oscillated frequency, a light emission intensity of plasma of a specific wavelength inside a processing container, and positions of movable plates of a tuner.

FIG. 11 is a view (1) illustrating a correlation between an oscillated frequency and a plasma density.

FIG. 12 is a view (2) illustrating a correlation between an oscillated frequency and a plasma density.

FIG. 13 is a view (3) illustrating a correlation between an oscillated frequency and a plasma density.

FIG. 14 is a flow chart illustrating an exemplary processing flow of a plasma processing method using a plasma processing apparatus according to an exemplary embodiment.

FIG. 15 is a view illustrating an exemplary configuration of a plasma processing apparatus according to another exemplary embodiment.

### DETAILED DESCRIPTION TO EXECUTE THE INVENTION

Hereinafter, various exemplary embodiments will be described in detail with reference to the drawings. In addition, identical or similar portions in the drawings will be denoted by the same reference numerals.

A plasma processing apparatus according to an exemplary embodiment, in an aspect, includes: a processing container; a placing table provided inside the processing container and configured to place a workpiece thereon; a gas supply mechanism configured to supply a processing gas used for a plasma reaction to the inside of the processing container; a plasma generating mechanism including a microwave oscillator and configured to bring the processing gas supplied to the inside of the processing container into a plasma state using microwaves oscillated by the microwave oscillator; and an adjustment unit configured such that, when each of a plurality of steps for plasma-processing the workpiece is performed, a frequency of microwaves oscillated by the microwave oscillator is adjusted to a predetermined target frequency for each of the steps, at a timing when each of the plurality of steps is switched.

In the plasma processing apparatus according to the present exemplary embodiment, in an aspect, the adjustment unit adjusts the frequency of the microwaves oscillated by the microwave oscillator to the target frequency different for each of the steps, at the timing when each of the plurality of steps is switched.

In the plasma processing apparatus according to the present exemplary embodiment, in an aspect, the adjustment unit keeps the frequency of the microwaves oscillated by the microwave oscillator at the target frequency for a time period during which a switched step is performed.

In the plasma processing apparatus according to the present exemplary embodiment, in an aspect, the target frequency is stored in association with each of the plurality of steps in a process recipe for performing a process, and the adjustment unit adjusts the frequency of the microwaves oscillated by the microwave oscillator to the target frequency associated with a switching destination step in the process recipe with reference to the process recipe at the timing when each of the plurality of steps is switched.

The plasma processing apparatus according to the present exemplary embodiment, in an aspect, further includes: an acquisition unit configured to acquire a correlation between the frequency of the microwaves oscillated by the microwave oscillator and a predetermined parameter to be applied to each of the plurality of steps, in a state where a separate subject to be processed from the workpiece is placed on the placing table before the plurality of steps is performed; and a specifying unit configured to specify the frequency of the microwaves corresponding to the parameter meeting a predetermined condition as the target frequency, by using the correlation acquired by the acquisition unit. When each of the plurality of steps is performed, the adjustment unit adjusts the frequency of the microwaves oscillated by the microwave oscillator to the target frequency specified by the specifying unit at the timing when each of the plurality of steps is switched.

In the plasma processing apparatus according to the present exemplary embodiment, in an aspect, the parameter is at least one of: (1) a light emission intensity of plasma of a specific wavelength inside the processing container, (2) a variation of the light emission intensity per unit time, (3) a position of a movable plate provided in a tuner to match impedances between the microwave oscillator and the processing container, (4) a power of traveling waves of the microwaves, (5) a power of reflected waves of the microwaves, (6) a pixel value indicating a plasma distribution obtained by an image processing, (7) a pressure inside the processing container, (8) a flow rate of the processing gas, (9) a bias power, and (10) a plasma density inside the processing container.

A plasma processing method according to an exemplary embodiment, in an aspect, uses a plasma processing apparatus including: a processing container; a placing table provided inside the processing container and configured to place a workpiece thereon; a gas supply mechanism configured to supply a processing gas used for a plasma reaction to the inside of the processing container; and a plasma generating mechanism including a microwave oscillator and configured to bring the processing gas supplied to the inside of the processing container into a plasma state using microwaves oscillated by the microwave oscillator, wherein when each of a plurality of steps for plasma-processing the workpiece is performed, a frequency of microwaves oscillated by the microwave oscillator is adjusted to a predetermined target frequency for each of the steps at a timing when each of the plurality of steps is switched.

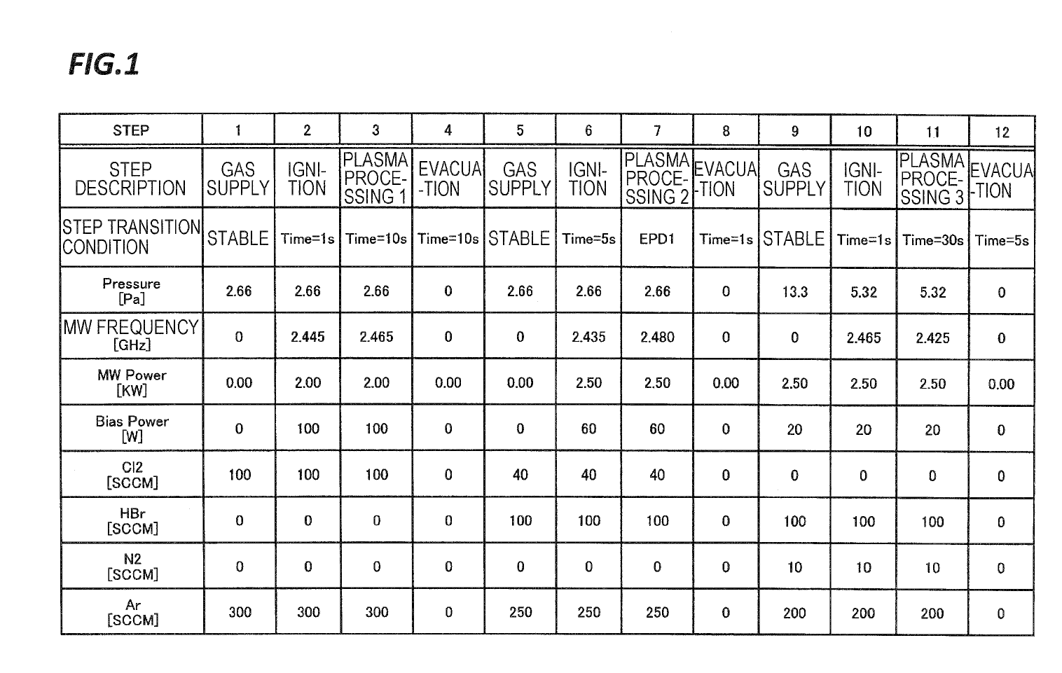

First, descriptions will be made on an exemplary processing flow of the plasma processing method using the plasma processing apparatus according to an exemplary embodiment. FIG. 1 is a view illustrating an exemplary processing flow of the plasma processing method according to an exemplary embodiment. FIG. 1 represents a plurality of consecutive STEPS 1 to 12 for plasma-processing a workpiece, and various conditions corresponding to the plurality of steps, respectively.

In FIG. 1, it is assumed that “STEP 1,” “STEP 5,” and “STEP 9” correspond to a gas supplying step for supplying a processing gas to be used for a plasma reaction to the inside of a processing container. It is assumed that “STEP 2,” “STEP 6,” and “STEP 10” correspond to an igniting step for bringing the processing gas into a plasma state using microwaves. It is assumed that “STEP 3,” “STEP 7,” and “STEP 11” correspond to a plasma-processing step for plasma-processing the workpiece by the plasma of the processing gas. It is assumed that “STEP 4,” “STEP 8,” and “STEP 12” correspond to an evacuating step for evacuating the inside of the processing container.

When each of the plurality of steps for plasma-processing the workpiece is performed, the plasma processing apparatus according to an exemplary embodiment adjusts a frequency of microwaves oscillated by a microwave oscillator to a predetermined target frequency for each of the steps, at a timing when each of the steps is switched. In the example of FIG. 1, when the igniting step of STEP 2 is performed, the plasma processing apparatus adjusts the frequency of the microwaves to “2.445 GHz” which is a predetermined target frequency for the igniting step of STEP 2. In addition, in the example of FIG. 1, when the plasma-processing step of STEP 3 is performed, the plasma processing apparatus adjusts the frequency of the microwaves to “2.465 GHz” which is a predetermined target frequency for the plasma-processing step of STEP 3.

In this way, when each of the plurality of steps for plasma-processing the workpiece is performed, the plasma processing apparatus according to an exemplary embodiment adjusts the frequency of the microwaves to a predetermined target frequency for each of the steps, at the timing when each of the steps is switched. For example, when the igniting step is performed, the plasma processing apparatus adjusts the frequency of the microwaves to a target frequency at which a processing gas is sufficiently brought into the plasma state. In addition, for example, when the plasma-processing step is performed, the plasma processing apparatus adjusts the frequency of the microwaves to a target frequency at which the uniformity of the plasma is maintained. As a result, according to the plasma processing apparatus of an exemplary embodiment, when each of the plurality of steps for plasma-processing the workpiece is performed, the frequency of the microwaves may be adjusted to an optimum frequency for each of the steps.

Further, according to the plasma processing apparatus of an exemplary embodiment, the following secondary effects are also obtained. That is, since the frequency at which plasma is most prone to be ignited may be set in the plasma igniting step, the ignition may be performed with a less power so that the consumption of an electrode member and the generation of particles may be suppressed. Further, since a change of a condition is not required between the igniting step and the process step, and the process step is ended only with the change of the frequency so that the process time is largely reduced. Further, since an optimum frequency varying depending on gas types and conditions is set in the process step, the microwaves are effectively absorbed to plasma, and as a result, the plasma density is high so that the plasma becomes stable, and the in-plane uniformity of the plasma density is high so that it is possible to provide a plasma processing method in which a difference in process condition for respective apparatuses is small. By setting a frequency avoiding a frequency region where a so-called mode jump in which the plasma state changes occurs, plasma with a large stable margin may be provided.

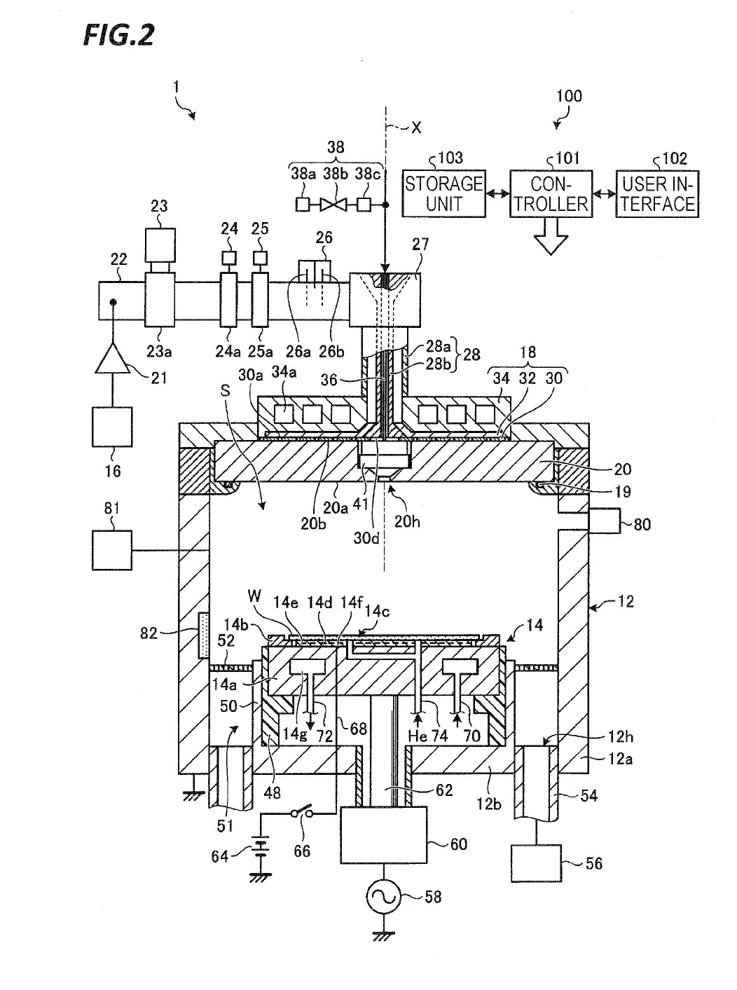

Next, descriptions will be made on an exemplary configuration of the plasma processing apparatus according to an exemplary embodiment. FIG. 2 is a view schematically illustrating the plasma processing apparatus according to an exemplary embodiment. A plasma processing apparatus 1 illustrated in FIG. 2 includes a processing container 12, a stage 14, a phase locked loop (PLL) oscillator 16, an antenna 18, a dielectric 20, and a control unit 100.

The processing container 12 defines a processing space S for performing the plasma-processing. The processing container 12 has a side wall 12a and a bottom portion 12b. The side wall 12a is formed in a substantially cylindrical shape. Hereinafter, at the center of the cylindrical shape of the side wall 12a, an extension axis-X of the cylindrical shape is virtually set, and the extension direction of the axis-X will be referred to as an axis-X direction. The bottom portion 12b is provided at the lower end side of the side wall 12a and covers the bottom side opening of the side wall 12a. An exhaust hole 12h for exhaust is provided on the bottom portion 12b. The upper end portion of the side wall 12a is opened.

The opening of the upper end portion of the side wall 12a is closed by a dielectric window 20. An O-ring 19 is interposed between the dielectric window 20 and the upper end portion of the side wall 12a. The dielectric window 20 is provided in the upper end portion of the side wall 12a via the O-ring 19. The sealing of the processing container 12 is more reliably implemented by the O-ring 19. The stage 14 is accommodated in the processing space S, and a workpiece W is placed on the stage 14. The dielectric window 20 has a facing surface 20a that faces the processing space S.

The PLL oscillator 16 oscillates microwaves of, for example, 2.45 GHz. The PLL oscillator 16 corresponds to an example of a microwave oscillator.

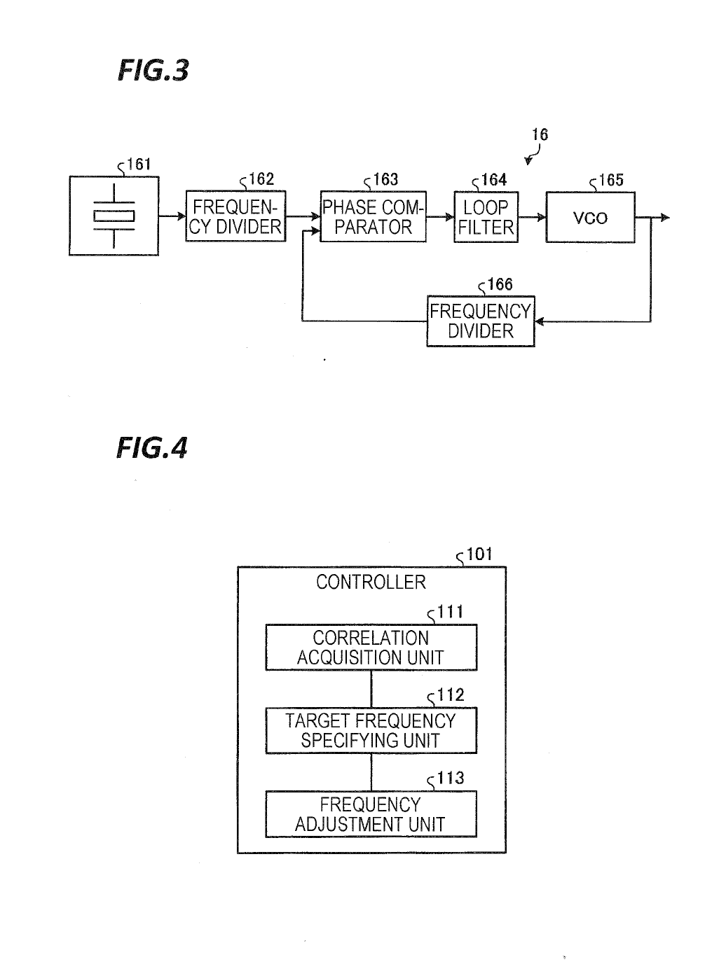

FIG. 3 is a view illustrating an exemplary configuration of the PLL oscillator in an exemplary embodiment. The PLL oscillator 16 includes a reference signal generator 161, a frequency divider 162, a phase comparator 163, a loop filter 164, a voltage controlled oscillator (VCO) 165, and a frequency divider 166.

The reference signal generator 161 generates a reference signal having a predetermined frequency and outputs the generated reference signal to the frequency divider 162.

The frequency divider 162 performs a dividing processing for dividing the frequency of the reference signal input from the reference signal generator 161 into 1/M (M is an integer) times, and outputs the signal obtained by the dividing processing to the phase comparator 163. In addition, the frequency divider 162 is controlled by the control unit 100.

The phase comparator 163 generates a voltage signal representing a phase difference between the signal input from the frequency divider 162 and a signal input from the frequency divider 166, and outputs the generated voltage signal to the loop filter 164.

The loop filter 164 removes a high frequency component from the voltage signal input from the phase comparator 163, and outputs the voltage signal from which the high frequency component has been removed, to the VCO 165.

The VCO 165 oscillates microwaves having a frequency which follows a value of the voltage signal. Some of the microwaves oscillated by the VCO 165 are input to the frequency divider 166.

The frequency divider 166 performs a dividing processing for dividing the frequency of the microwaves input from the VCO 165 into 1/N (N is an integer) times, and outputs the signal obtained by the dividing processing to the phase comparator 163. In addition, at least one of the frequency division ratio M in the frequency divider 162 and the frequency division ratio N in the frequency divider 166 is controlled by the control unit 100 to be described later. When at least one of the frequency division ratio M and the frequency division ratio N is controlled, the frequency of the microwaves output from the PLL oscillator 16 varies. When it is assumed that the frequency of the microwaves output from the PLL oscillator 16 is fₒᵤₜ, and the frequency of the reference signal generated by the reference signal generator 161 is fᵢₙ, the fₒᵤₜ is represented by the following expression (1)

fₒᵤₜ=fᵢₙ×N/M (1)

Referring back to FIG. 2, in an exemplary embodiment, the plasma processing apparatus 1 further includes a microwave amplifier 21, a waveguide 22, an isolator 23, a detector 24, a detector 25, a tuner 26, a mode converter 27, and a coaxial waveguide 28.

The PLL oscillator 16 is connected to the waveguide 22 via the microwave amplifier 21. The microwave amplifier 21 amplifies the microwaves oscillated by the PLL oscillator 16, and outputs the amplified microwaves to the waveguide 22. The waveguide 22 is, for example, a rectangular waveguide. The waveguide 22 is connected to the mode converter 27, and the mode converter 27 is connected to the top end of the coaxial waveguide 28.

The isolator 23 is connected to the waveguide 22 via a directional coupler 23a. The directional coupler 23a extracts reflected waves of the microwaves which are reflected from the processing container 12 side and outputs the extracted reflected waves of the microwaves to the isolator 23. The isolator 23 converts the reflected waves of the microwaves input from the directional coupler 23a into heat by, for example, a load.

The detector 24 is connected to the waveguide 22 via the directional coupler 24a. The directional coupler 24a extracts traveling waves of the microwaves which travel toward the processing container 12 side and outputs the extracted traveling waves of the microwaves to the detector 24. The detector 24 detects a power of the traveling waves of the microwaves input from the directional coupler 24a and outputs the detected power to the control unit 100.

The detector 25 is connected to the waveguide 22 via the directional coupler 25a. The directional coupler 25a extracts reflected waves of the microwaves which are reflected from the processing container 12 side and outputs the extracted reflected waves of the microwaves to the detector 25. The detector 25 detects a power of the reflected waves of the microwaves input from the directional coupler 25a and outputs the detected power to the control unit 100.

The tuner 26 is provided in the waveguide 22 and has a function to match impedances between the PLL oscillator 16 and the processing container 12. The tuner 26 has movable plates 26a and 26b provided to movably protrude into the internal space of the waveguide 22. The tuner 26 matches the impedances between the PLL oscillator 16 and the processing container 12 by controlling the protruding positions of the movable 26a and 26b with respect to a reference position.

The coaxial waveguide 28 extends along the axis-X. The coaxial waveguide 28 includes an outer conductor 28a and an inner conductor 28b. The outer conductor 28a has a substantially cylindrical shape extending in the axis-X direction. The inner conductor 28b is provided inside the outer conductor 28a. The inner conductor 28b has a substantially cylindrical shape extending along the axis-X.

The microwaves generated by the PLL oscillator 16 are guided to the mode converter 27 via the tuner 26 and the waveguide 22. The mode converter 27 converts a mode of the microwaves and supplies the mode-converted microwaves to the coaxial waveguide 28. The microwaves from the coaxial waveguide 28 are supplied to the antenna 18.

The antenna 18 radiates plasma excitation microwaves based on the microwaves generated by the PLL oscillator 16. The antenna 18 has a slot plate 30, a dielectric plate 32, and a cooling jacket 34. The antenna 18 is provided on the surface 20b of the dielectric window 20 opposite to the facing surface 20a, and radiates the plasma excitation microwaves into the processing space S through the dielectric window 20, based on the microwaves generated by the PLL oscillator 16. In addition, for example, the PLL oscillator 16 and the antenna 18 correspond to an example of a plasma generating mechanism that supplies electromagnetic energy for bringing the processing gas introduced into the processing space S, into the plasma state.

The slot plate 30 is formed in a substantially disc shape of which the plate surface is orthogonal to the axis-X. The slot plate 30 is disposed on the surface 20b of the dielectric window 20 opposite to the facing surface 20a, with the plate surface of the slot plate 30 being aligned with the dielectric window 20. A plurality of slots 30a is arranged circumferentially around the axis-X on the slot plate 30. The slot plate 30 constitutes a radial line slot antenna. The slot plate 30 is formed in a conductive metal disc shape. The plurality of slots 30a is formed on the slot plate 30. In addition, a through hole 30d is formed at the central portion of the slot plate 30 such that a conduit 36 to be described later may penetrate the through hole.

The dielectric plate 32 is formed in a substantially disc shape of which the plate surface is orthogonal to the axis-X. The dielectric plate 32 is provided between the slot plate 30 and the lower surface of the cooling jacket 34. The dielectric plate 32 is made of, for example, quartz, and has a substantially disc shape.

The surface of the cooling jacket 34 has conductivity. A flow path 34a is formed inside the cooling jacket 34 such that a coolant may flow therethrough, and the dielectric plate 32 and the slot plate 30 are cooled by the circulation of the coolant. The lower end of the outer conductor 28a is electrically connected to the top surface of the cooling jacket 34. In addition, the lower end of the inner conductor 28b is electrically connected to the slot plate 30 through the holes formed at the central portions of the cooling jacket 34 and the dielectric plate 32.

The microwaves from the coaxial waveguide 28 are propagated to the dielectric plate 32 and introduced into the processing space S through the dielectric window 20 from the slots 30a of the slot plate 30. In an exemplary embodiment, the conduit 36 passes through the internal hole of the inner conductor 28b of the coaxial waveguide 28. The through hole 30d is formed at the central portion of the slot plate 30 such that the conduit 36 may penetrate the through hole 30d. The conduit 36 extends along the axis-X and is connected to a gas supply system 38.

The gas supply system 38 supplies the processing gas for processing the workpiece W to the conduit 36. The gas supply system 38 may include a gas source 38a, a valve 38b, and a flow rate controller 38c. The gas source 38a is a gas source of the processing gas. The valve 38b performs switching between the supply of the processing gas from the gas source 38a and a stop of the supply. The flow rate controller 38c is, for example, a mass flow controller, and adjusts a flow rate of the processing gas from the gas source 38a. In addition, the gas supply system 38 corresponds to an example of the gas supply mechanism that introduces the processing gas used for a plasma reaction into the processing space S.

In an exemplary embodiment, the plasma processing apparatus 1 may further include an injector 41. The injector 41 supplies the gas from the conduit 36 to the through hole 20h formed on the dielectric window 20. The gas supplied to the through hole 20h of the dielectric window 20 is supplied into the processing space S. In the following descriptions, the gas supply route constituted by the conduit 36, the injector 41, and the through hole 20h may be referred to as a “central gas introducing portion.”

The stage 14 is provided opposite to the dielectric window 20 in the axis-X direction. The stage 14 is provided such that the processing space S is interposed between the dielectric window 20 and the stage 14. The workpiece W is placed on the stage 14. In an exemplary embodiment, the stage 14 includes a support 14a, a focus ring 14b, and an electrostatic chuck 14c. The stage 14 corresponds to an example of a placing table.

The support 14a is supported by a cylindrical support 48. The cylindrical support 48 is formed of an insulating material and extends vertically upward from the bottom portion 12b. Further, a conductive cylindrical support 50 is provided on the outer circumference of the cylindrical support 48. The cylindrical support 50 extends vertically upward from the bottom portion 12b of the processing container 12 along the outer circumference of the cylindrical support 48. An annular exhaust path 51 is formed between the cylindrical support 50 and the side wall 12a.

An annular baffle plate 52 provided with a plurality of through holes is attached to the top portion of the exhaust path 51. An exhaust device 56 is connected to the lower portion of the exhaust hole 12h via an exhaust pipe 54. The exhaust device 56 includes an automatic pressure control (APC) valve and a vacuum pump such as, for example, a turbo molecular pump. By the exhaust device 56, the processing space S inside the processing container 12 may be decompressed to a desired degree of vacuum.

The support 14a also serves as a high frequency electrode. A high frequency power supply 58 for RF bias is electrically connected to the support 14a via a power feed rod 62 and a matching unit 60. The high frequency power supply 58 outputs a high frequency power of a constant frequency suitable for controlling the energy of ions to be drawn into the workpiece W, e.g., 13.65 MHz (hereinafter, appropriately referred to as a “bias power”), with a predetermined power. The matching unit 60 accommodates a matcher to take a matching between an impedance of the high frequency power supply 58 side and an impedance of a load side which is mainly an electrode, plasma, or the processing container 12. The matcher includes a blocking capacitor for self-bias generation.

The electrostatic chuck 14c is provided on the top surface of the support 14a. The electrostatic chuck 14c holds the workpiece W by an electrostatic attraction force. The focus ring 14b is provided radially outside the electrostatic chuck 14c to annularly surround the surrounding of the workpiece W. The electrostatic chuck 14c includes an electrode 14d, an insulating film 14e, and an insulating film 14f. The electrode 14d is formed of a conductive film and provided between the insulating film 14e and the insulating film 14f. A high pressure DC power supply 64 is electrically connected to the electrode 14d via a switch 66 and a coated line 68. The electrostatic chuck 14c may attract and hold the workpiece W by a coulomb force generated by a DC voltage applied from the DC power supply 64.

An annular coolant cavity 14g is provided inside the support 14a to extend circumferentially. A coolant having a predetermined temperature (e.g., cooling water) is circulated and supplied to the coolant cavity 14g from a chiller unit (not illustrated) through pipes 70 and 72. The temperature of the top surface of the electrostatic chuck 14c is controlled by the temperature of the coolant. A heat transfer gas (e.g., He gas) is supplied between the top surface of the electrostatic chuck 14c and the rear surface of the workpiece W through a gas supply pipe 74, and the temperature of the workpiece W is controlled by the temperature of the top surface of the electrostatic chuck 14.

In an exemplary embodiment, the plasma processing apparatus 1 further includes a spectroscopic sensor 80, a vacuum gauge 81, and a plasma distribution imaging camera 82. The spectroscopic sensor 80 detects a light emission intensity of plasma of a specific wavelength inside the processing container 12, and outputs the detected light emission intensity to the control unit 100. The vacuum gauge 81 measures a pressure inside the processing container 12, and outputs the measured pressure to the control unit 100. The plasma distribution imaging camera 82 images a plasma distribution in the processing space S, and outputs the image obtained by the imaging to the control unit 100.

The control unit 100 is connected to each of the components of the plasma processing apparatus 1, and integrally controls the respective components. The control unit 100 includes a controller 101 provided with a central processing unit (CPU), a user interface 102, and a storage unit 103.

By executing programs and process recipes stored in the storage unit 103, the controller 101 integrally controls, for example, the PLL oscillator 16, the stage 14, the gas supply system 38, the exhaust device 56, the spectroscopic sensor 80, the vacuum gauge 81, and the plasma distribution imaging camera 82.

The user interface 102 has, for example, a keyboard or a touch panel by which a process manager performs, for example, an input operation of a command in order to manage the plasma processing apparatus 1, and a display configured to visualize and display an operating state of the plasma processing apparatus 1.

The storage unit 103 stores, for example, control programs (software) for implementing the various processes that are performed in the plasma processing apparatus 1 by the control of the controller 101, or process recipes in which, for example, process condition data is recorded to perform the processes. In an exemplary embodiment, target frequencies are stored in the process recipes in association with a plurality of steps, respectively. For example, the process recipes store target frequencies and a plurality of steps which are associated with each other as in the aspect represented in FIG. 1. The controller 101 reads the various control programs from the storage unit 103 according to necessity, e.g., an instruction from the user interface 102, and executes the programs so as to implement various functional blocks.

FIG. 4 is a view illustrating an example of the functional blocks of the controller in an exemplary embodiment. As illustrated in FIG. 4, the controller 101 has a correlation acquisition unit 111, a target frequency specifying unit 112, and a frequency adjustment unit 113, as the functional blocks.

The correlation acquisition unit 111 acquires a correlation between the frequency of the microwaves oscillated by the PLL oscillator 16 (hereinafter, appropriately referred to as the “oscillated frequency”) and a predetermined parameter to be applied to each of the plurality of steps, in a state where a separate subject to be processed from the workpiece W is placed on the stage 14 before the plurality of steps is performed. Here, the separate subject to be processed from the workpiece W is, for example, a dummy wafer on which an oxide film is formed (e.g., a silicon substrate). In addition, the correlation indicates a relationship in which the oscillated frequency and the predetermined parameter are associated with each other according to a specific regularity. In addition, the parameter is at least one of (1) a light emission intensity of plasma of a specific wavelength inside the processing container 12, (2) a variation of the light emission intensity per unit time, (3) positions of the movable plates 26a and 26b provided in the tuner 26 to match the impedances between the PLL oscillator 16 and the processing container 12, (4) a power of the traveling waves of the microwaves, (5) a power of the reflected waves of the microwaves, (6) a pixel value indicating a plasma distribution obtained by an image processing, (7) a pressure inside the processing container 12, (8) a flow rate of the processing gas, (9) a bias power, and (10) a plasma density inside the processing container 12.

Here, descriptions will be made on an example of a correlation acquiring process by the correlation acquisition unit 11. The correlation acquisition unit 111 acquires a predetermined parameter to be applied to each of the plurality of steps, in the state where a separate subject to be processed from the workpiece W is placed on the stage 14 before the plurality of steps is performed. For example, the correlation acquisition unit 111 acquires the parameters described in (1) and (2) above from the spectroscopic sensor 80. Further, the correlation acquisition unit 111 acquires the parameter described in (3) above from the tuner 26. Further, the correlation acquisition unit 111 acquires the parameter described in (4) above from the detector 24. Further, the correlation acquisition unit 111 acquires the parameter described in (5) above from the detector 25. Further, the correlation acquisition unit 111 acquires the parameter described in (6) above, by performing a predetermined image processing for image data input from the plasma distribution imaging camera 82. Further, the correlation acquisition unit 111 acquires the parameter described in (7) above from the vacuum gauge 81. Further, the correlation acquisition unit 111 acquires the parameter described in (8) above from the flow rate controller 38c. Further, the correlation acquisition unit 111 acquires the parameter described in (9) above from the high frequency power supply 58. Further, the correlation acquisition unit 111 acquires the parameter described in (10) above from a plasma density gauge (not illustrated) attached to the processing container 12. Subsequently, the correlation acquisition unit 111 acquires a correlation between the oscillated frequency and the parameters by representing variations of the parameters depending on the oscillated frequency in graphs.

The target frequency specifying unit 112 specifies a frequency of microwaves corresponding to the parameter meeting a predetermined condition as a target frequency, by using the correlation acquired from the correlation acquisition unit 111. The target frequency is a predetermined frequency for each of the plurality of steps for plasma-processing the workpiece W. For example, the target frequency is predetermined such that the processing gas is sufficiently brought into the plasma state for the igniting step for bringing the processing gas into the plasma state using microwaves. In addition, for example, the target frequency is predetermined such that the uniformity of plasma is maintained for the plasma-processing step for plasma-processing the workpiece W with the plasma of the processing gas.

In addition, the target frequency specifying unit 112 may cause the specified target frequency to be stored as a portion of the process recipes in the storage unit 103. In this case, the target frequency is stored in association with each of the plurality of steps in the process recipes stored in the storage unit 103.

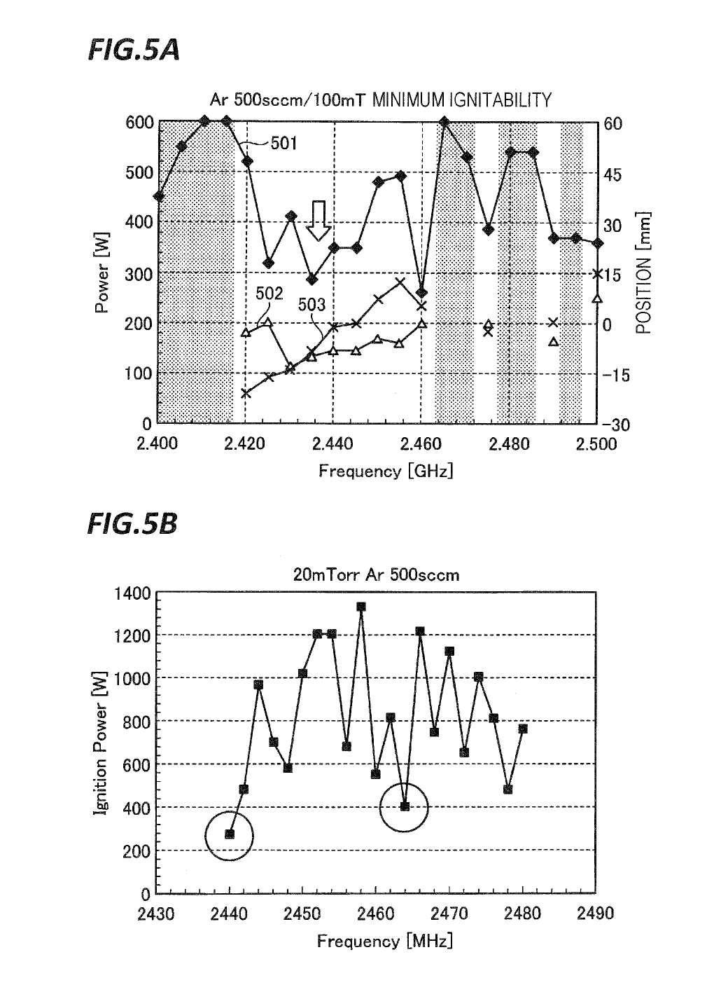

Here, descriptions will be made on an example of the target frequency specifying process by the target frequency specifying unit 112 while describing a plurality of examples of the correlation acquired by the correlation acquisition unit 111. FIG. 5A is a view illustrating a correlation among the oscillated frequency, a power of the traveling waves of the microwaves, and positions of the movable plates of the tuner. The correlation represented in FIG. 5A is acquired by the correlation acquisition unit 111. In FIG. 5A, the horizontal axis indicates the frequency of the microwaves oscillated by the PLL oscillator 16, i.e., the oscillated frequency (GHz), and the vertical axis indicates the power (W) of the traveling waves of the microwaves and the positions (mm) of the movable plates 26a and 26b of the tuner 26. In addition, in FIG. 5A, the graph 501 represents a change of the power of the traveling waves of the microwaves when plasma of the processing gas is generated inside the processing container 12. The graph 502 represents a change of the position of the movable plate 26a of the tuner 26. The graph 503 represents a change of the position of the movable plate 26b of the tuner 26. In addition, in FIG. 5A, the shaded areas represent the oscillated frequency when plasma of the processing gas is not generated inside the processing container 12. In addition, in FIG. 5A, it is assumed that 500 sccm Ar is used as the processing gas, and the pressure inside the processing container 12 is 13.3 Pa (100 mTorr).

As represented in the graph 501 of FIG. 5A, the power of the traveling waves of the microwaves when plasma of the processing gas is generated inside the processing container 12 becomes the lowest when the oscillated frequency is in a range of 2.43 GHz to 2.45 GHz. In other words, when the parameters meet the predetermined condition where the power of the traveling waves of the microwaves when plasma of the processing gas is generated inside the processing container 12 becomes the lowest, the frequency of the microwaves corresponding to the parameters meeting the predetermined condition is in the range of 2.43 GHz to 2.45 GHz. That is, when the frequency of the microwaves is in the range of 2.43 GHz to 2.45 GHz, there is a high possibility that the processing gas will be sufficiently brought into the plasma state in the igniting step for bringing the processing gas into the plasma state using microwaves. Thus, the target frequency specifying unit 112 selects the frequency of the microwaves from the range of 2.43 GHz to 2.45 GHz, and specifies the selected frequency of the microwaves as a predetermined target frequency for the igniting step.

FIG. 5B is a view illustrating a correlation between the oscillated frequency and a power of the traveling waves of the microwaves. The correlation represented in FIG. 5B is acquired by the correlation acquisition unit 111. In FIG. 5B, the horizontal axis indicates the frequency of the microwaves oscillated by the PLL oscillator 16, i.e., the oscillated frequency (MHz), and the vertical axis indicates the power (W) of the traveling waves of the microwaves when plasma of the processing is generated inside the processing container 12. In addition, in FIG. 5B, it is assumed that 500 sccm Ar is used as the processing gas, and the pressure inside the processing container 12 is 2.67 Pa (20 mTorr).

As illustrated in FIG. 5B, the power of the traveling waves of the microwaves when plasma of the processing gas is generated inside the processing container 12 becomes relatively low when the oscillated frequency is 2,440 MHz and 2,464 MHz. In other words, when the parameter meets the predetermined condition where the power of the traveling waves of the microwaves when plasma of the processing gas is generated inside the processing container 12 is equal to or less than a predetermined threshold value (e.g., 400 W), the frequency of the microwaves corresponding to the parameter meeting the predetermined condition is 2,440 MHz and 2,464 MHz. That is, when the frequency of the microwaves is 2,440 MHz and 2,464 MHz, the processing gas may be brought into the plasma state by the relatively low power of the traveling waves of the microwaves in the igniting step. Thus, the target frequency specifying unit 112 selects any one of 2,440 MHz and 2,464 MHz as the frequency of the microwaves, and specifies the selected frequency of the microwaves as a predetermined target frequency for the igniting step.

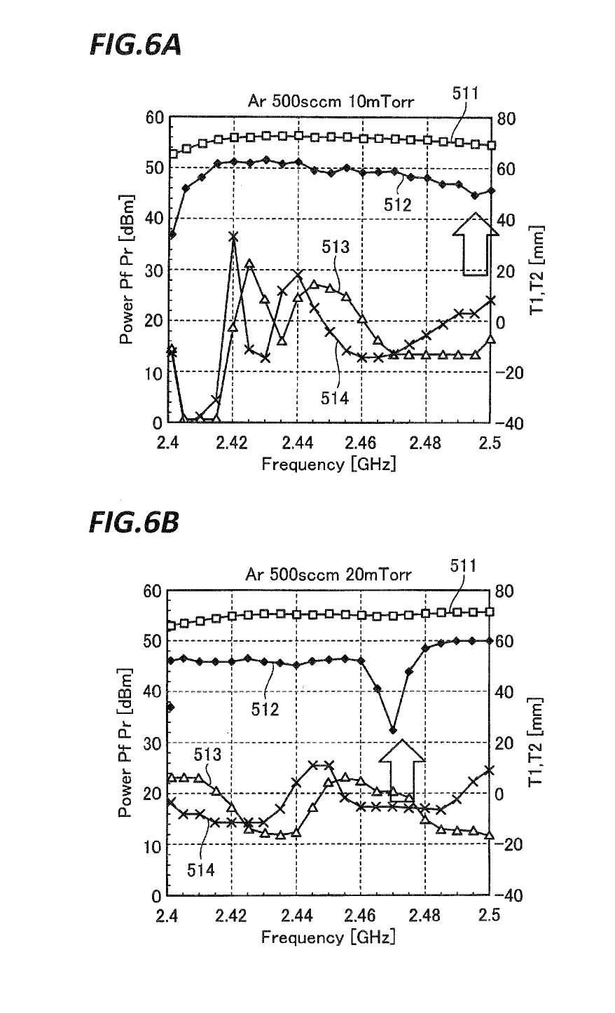

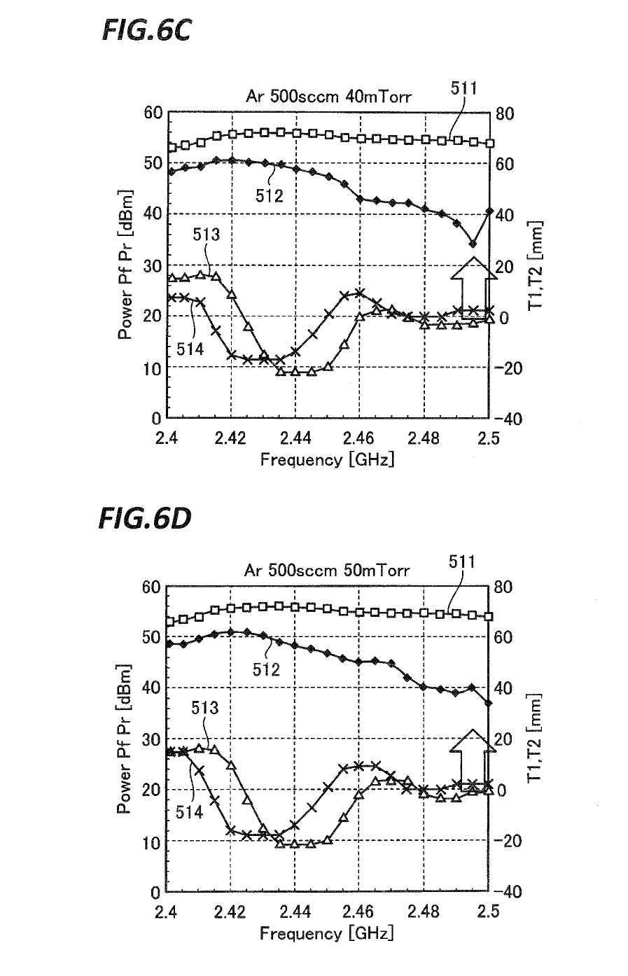

FIGS. 6A to 6D are views illustrating correlations among the oscillated frequency, with a power of the traveling waves of the microwaves, a power of the reflected waves of the microwaves, and positions of the movable plates of the tuner. The correlations represented in FIGS. 6A to 6D are acquired by the correlation acquisition unit 111. In FIGS. 6A to 6D, the horizontal axis indicates the frequency of the microwaves oscillated by the PLL oscillator 16, i.e., the oscillated frequency (GHz), and the vertical axis indicates the power (dBm) of the traveling waves of the microwaves, the power (dBm) of the reflected waves of the microwaves, and the positions (mm) of the movable plates of the tuner. In addition, in FIGS. 6A to 6D, the graph 511 represents a change of the power of the traveling waves of the microwaves. The graph 512 represents a change of the power of the reflected waves of the microwaves. The graph 513 represents a change of the position of the movable plate 26a of the tuner 26. The graph 514 represents a change of the position of the movable plate 26b of the tuner 26.

In addition, in FIG. 6A, it is assumed that 500 sccm Ar is used as the processing gas, and the pressure inside the processing container 12 is 1.33 Pa (10 mTorr). In FIG. 6B, it is assumed that 500 sccm Ar is used as the processing gas, and the pressure inside the processing container 12 is 2.67 Pa (20 mTorr). In FIG. 6C, it is assumed that 500 sccm Ar is used as the processing gas, and the pressure inside the processing container 12 is 5.33 Pa (40 mTorr). In FIG. 6D, it is assumed that 500 sccm Ar is used as the processing gas, and the pressure inside the processing container 12 is 6.67 Pa (50 mTorr).

As represented by the graph 512 of FIG. 6A, in the state where the pressure inside the processing container 12 is 10 mTorr, the power of the reflected waves of the microwaves becomes the lowest when the oscillated frequency is 2.495 GHz. In other words, when the parameters meet the predetermined condition where the power of the reflected waves of the microwaves becomes the lowest, the frequency of the microwaves corresponding to the parameters meeting the predetermined condition is 2.495 GHz. That is, when the frequency of the microwaves is 2.495 GHz, the influence of the reflected waves of the microwaves on plasma is suppressed so that there is a high possibility that the uniformity of the plasma will be maintained in the plasma-processing step for plasma-processing the workpiece by the plasma of the processing gas. Thus, the target frequency specifying unit 112 specifies 2.495 GHz as the predetermined target frequency for the plasma-processing step.

In addition, as represented in the graph 512 of FIG. 6B, in the state where the pressure inside the processing container 12 is 20 mTorr, the power of the reflected waves of the microwaves becomes the lowest when the oscillated frequency is 2.47 GHz. In other words, when the parameters meet the predetermined condition where the power of the reflected waves of the microwaves becomes the lowest, the frequency of the microwaves corresponding to the parameters meeting the predetermined condition is 2.47 GHz. That is, when the frequency of the microwaves is 2.47 GHz, the influence of the reflected waves of the microwaves on plasma is suppressed so that there is a high possibility that the uniformity of the plasma will be maintained in the plasma-processing step for plasma-processing the workpiece by the plasma of the processing gas. Thus, the target frequency specifying unit 112 specifies 2.47 GHz as a predetermined target frequency for the plasma-processing step.

In addition, as represented in the graph 512 of FIG. 6C, in the state where the pressure inside the processing container 12 is 40 mTorr, the power of the reflected waves of the microwaves becomes the lowest when the oscillated frequency is 2.495 GHz. In other words, when the parameters meet the predetermined condition where the power of the reflected waves of the microwaves becomes the lowest, the frequency of the microwaves corresponding to the parameters meeting the predetermined condition is 2.495 GHz. That is, when the frequency of the microwaves is 2.495 GHz, the influence of the reflected waves of the microwaves on plasma is suppressed so that there is a high possibility that the uniformity of the plasma will be maintained in the plasma-processing step for plasma-processing the workpiece by the plasma of the processing gas. Thus, the target frequency specifying unit 112 specifies 2.495 GHz as a predetermined target frequency for the plasma-processing step.

In addition, as represented in the graph 512 of FIG. 6D, in the state where the pressure inside the processing container 12 is 50 mTorr, the power of the reflected waves of the microwaves becomes the lowest when the oscillated frequency is 2.5 GHz. In other words, when the parameters meet the predetermined condition that the power of the reflected waves of the microwaves becomes the lowest, the frequency of the microwaves corresponding to the parameters meeting the predetermined condition is 2.5 GHz. That is, when the frequency of the microwaves is 2.5 GHz, the influence of the reflected waves of the microwaves on plasma is suppressed so that there is a high possibility that the uniformity of the plasma will be maintained in the plasma-processing step for plasma-processing the workpiece by the plasma of the processing gas. Thus, the target frequency specifying unit 112 specifies 2.5 GHz as a predetermined target frequency for the plasma-processing step.

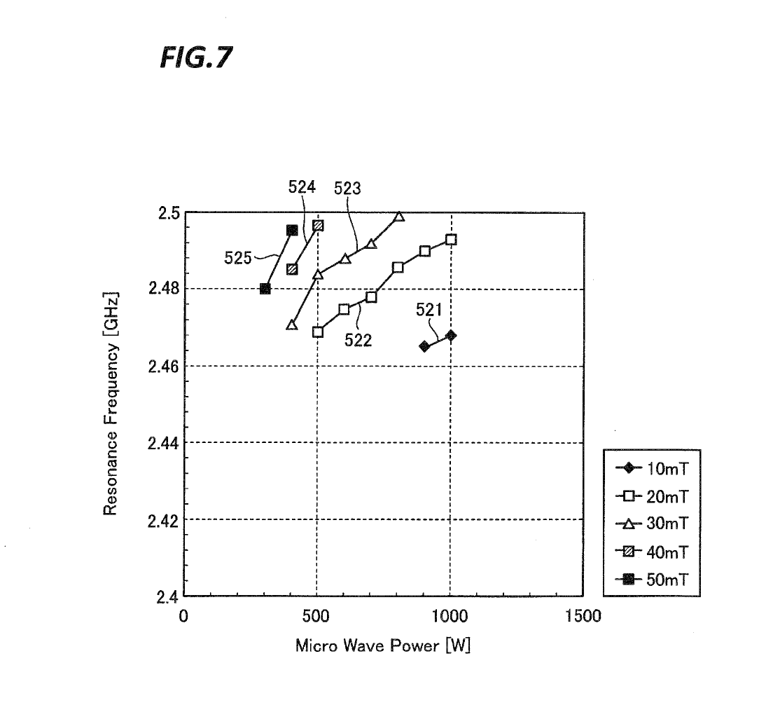

FIG. 7 is a view illustrating a correlation among the oscillated frequency when the power of the reflected waves of the microwaves becomes the lowest, the power of the traveling waves of the microwaves, and the pressure inside the processing container. The correlation represented in FIG. 7 is acquired by the correlation acquisition unit 111. In FIG. 7, the horizontal axis indicates the power (W) of the traveling waves of the microwaves, and the vertical axis indicates the oscillated frequency when the power of the reflected waves of the microwaves becomes the lowest, i.e., a resonance frequency (GHz). In addition, in FIG. 7, the graph 521 represents a change of the resonance frequency when the pressure inside the processing container 12 is 1.33 Pa (10 mTorr). The graph 522 represents a change of the resonance frequency when the pressure inside the processing container 12 is 2.67 Pa (20 mTorr). The graph 523 represents a change of the resonance frequency when the pressure inside the processing container 12 is 4.00 Pa (30 mTorr). The graph 524 represents a change of the resonance frequency when the pressure inside the processing container 12 is 5.33 Pa (40 mTorr). The graph 525 represents a change of the resonance frequency when the pressure inside the processing container 12 is 6.67 Pa (50 mTorr).

As illustrated in FIG. 7, when the frequency of the microwaves is the resonance frequency, the influence of the reflected waves of the microwaves on plasma is suppressed so that there is a high possibility that the uniformity of the plasma will be maintained in the plasma-processing step for plasma-processing the workpiece by the plasma of the processing gas. Thus, the target frequency specifying unit 112 specifies the resonance frequency as a predetermined target frequency for the plasma-processing step.

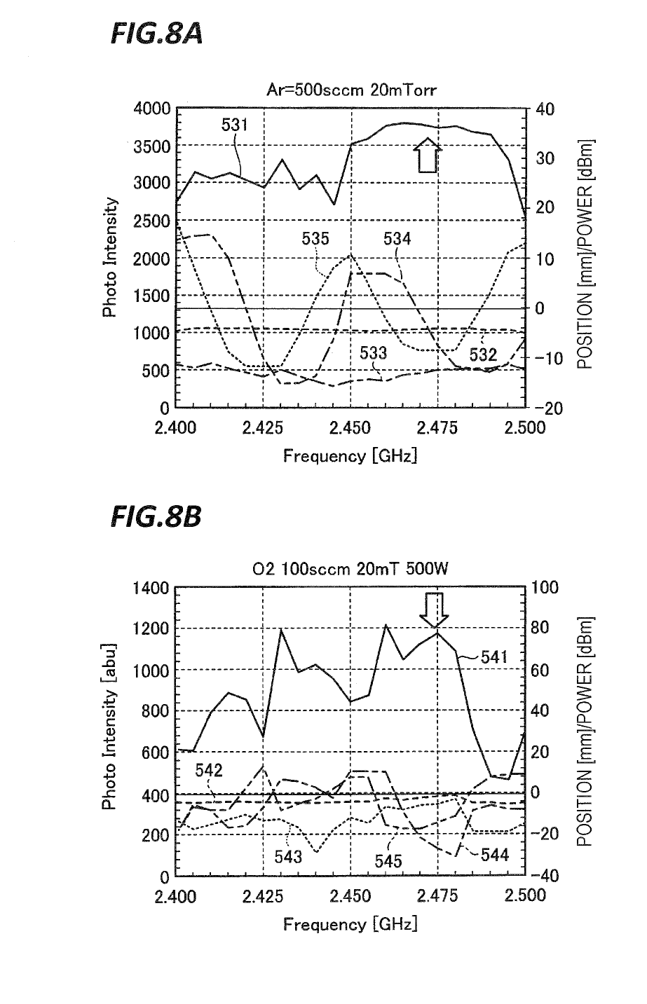

FIGS. 8A and 8B are views illustrating correlations of the oscillated frequency, with a light emission intensity of plasma of a specific wavelength inside the processing container, a power of the reflected waves of the microwaves, and positions of the movable plates of the tuner. The correlations represented in FIGS. 8A and 8B are acquired by the correlation acquisition unit 111. In FIGS. 8A and 8B, the horizontal axis indicates the frequency of the microwaves oscillated by the PLL oscillator 16, i.e., the oscillated frequency (GHz), and the vertical axis indicates the power (dBm) of the traveling waves of the microwaves, the power (dBm) of the reflected waves of the microwaves, the positions (mm) of the movable plates of the tuner, and the light emission intensity (abu) of plasma.

In addition, in FIG. 8A, the graph 531 represents a change of the light emission intensity of plasma of a wavelength corresponding to Ar when 500 sccm Ar is supplied as the processing gas to the inside of the processing container 12. The graph 532 represents a change of the power of the traveling waves of the microwaves. The graph 533 represents a change of the power of the reflected waves of the microwaves. The graph 534 represents a change of the position of the movable plate 26a of the tuner 26. The graph 535 represents a change of the position of the movable plate 26b of the tuner 26.

In addition, in FIG. 8B, the graph 541 represents a change of the light emission intensity of plasma of a wavelength corresponding to O₂ when 100 sccm O₂ is supplied as the processing gas to the inside of the processing container 12. The graph 542 represents a change of the power of the traveling waves of the microwaves. The graph 543 represents a change of the power of the reflected waves of the microwaves. The graph 544 represents a change of the position of the movable plate 26a of the tuner 26. The graph 545 represents a change of the position of the movable plate 26b of the tuner 26.

As represented in the graph 531 of FIG. 8A, the light emission intensity of the plasma of the wavelength corresponding to Ar becomes relatively high when the oscillated frequency is in a range of 2.450 GHz to 2.485 GHz. In other words, when the parameters meet the predetermined condition where the light emission intensity of the plasma of the wavelength corresponding to Ar becomes relatively high, the frequency of the microwaves corresponding to the parameters meeting the predetermined condition is in the range of 2.450 GHz to 2.485 GHz. That is, when the frequency of the microwaves is in the range of 2.450 GHz to 2.485 GHz, Ar is effectively brought into the plasma state so that there is a high possibility that the uniformity of the plasma will be maintained in the plasma-processing step for plasma-processing the workpiece by the plasma of the processing gas. Thus, the target frequency specifying unit 112 selects the frequency of the microwaves from the range of 2.450 GHz to 2.485 GHz, and specifies the selected frequency of the microwaves as a predetermined target frequency for the plasma-processing step.

In addition, as represented in the graph 541 of FIG. 8B, the light emission intensity of the plasma of the wavelength corresponding to O₂ becomes relatively high when the oscillated frequency is in a range of 2.460 GHz to 2.480 GHz. In other words, when the parameters meet the predetermined condition where the light emission intensity of the plasma of the wavelength corresponding to O₂ becomes relatively high, the frequency of the microwaves corresponding to the parameters meeting the predetermined condition is in the range of 2.460 GHz to 2.480 GHz. That is, when the frequency of the microwaves is in the range of 2.460 GHz to 2.480 GHz, O₂ is effectively brought into the plasma state so that there is a high possibility that the uniformity of the plasma will be maintained in the plasma-processing step for plasma-processing the workpiece by the plasma of the processing gas. Thus, the target frequency specifying unit 112 selects the frequency of the microwaves from the range of 2.460 GHz to 2.480 GHz, and specifies the selected frequency of the microwaves as a predetermined target frequency for the plasma-processing step.

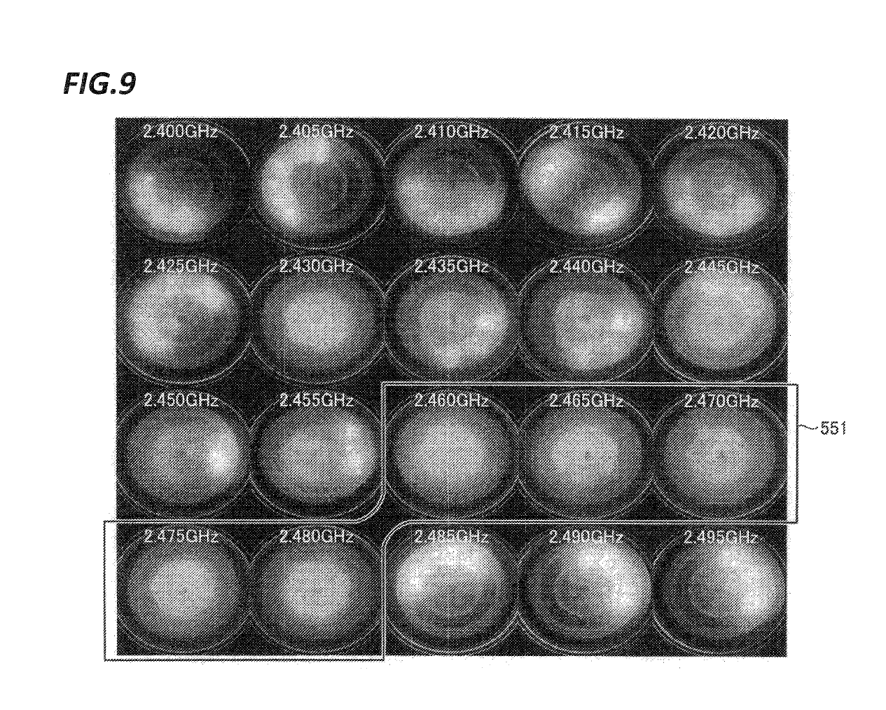

FIG. 9 is a view illustrating a correlation between the oscillated frequency and a pixel value indicating a plasma distribution. The correlation represented in FIG. 9 is acquired by the correlation acquisition unit 111. In FIG. 9, the pixel value indicating the plasma distribution is represented by gradation of color. Here, it is assumed that the plasma density inside the processing container 12 is high as the color is close to white, and the plasma density inside the processing container 12 is low as the color is close to black. Further, in FIG. 9, it is assumed that O₂ is used as the processing gas.

As represented by the frame 551 of FIG. 9, the pixel value indicating the plasma distribution becomes uniform within a predetermined allowed specification when the oscillated frequency is in a range of 2.460 GHz to 2.480 GHz. In other words, when the parameter meets the predetermined condition where the pixel value indicating the plasma distribution becomes uniform with the predetermined allowed specification, the frequency of the microwaves corresponding to the parameter meeting the predetermined condition is in the range of 2.460 GHz to 2.480 GHz. That is, when the frequency of the microwaves is in the range of 2.460 GHz to 2.480 GHz, there is a high possibility that the uniformity of the plasma will be maintained in the plasma-processing step for plasma-processing the workpiece by the plasma of the processing gas. Thus, the target frequency specifying unit 112 selects the frequency of the microwaves from the range of 2.460 GHz to 2.480 GHz, and specifies the selected frequency of the microwaves as a predetermined target frequency for the plasma-processing step.

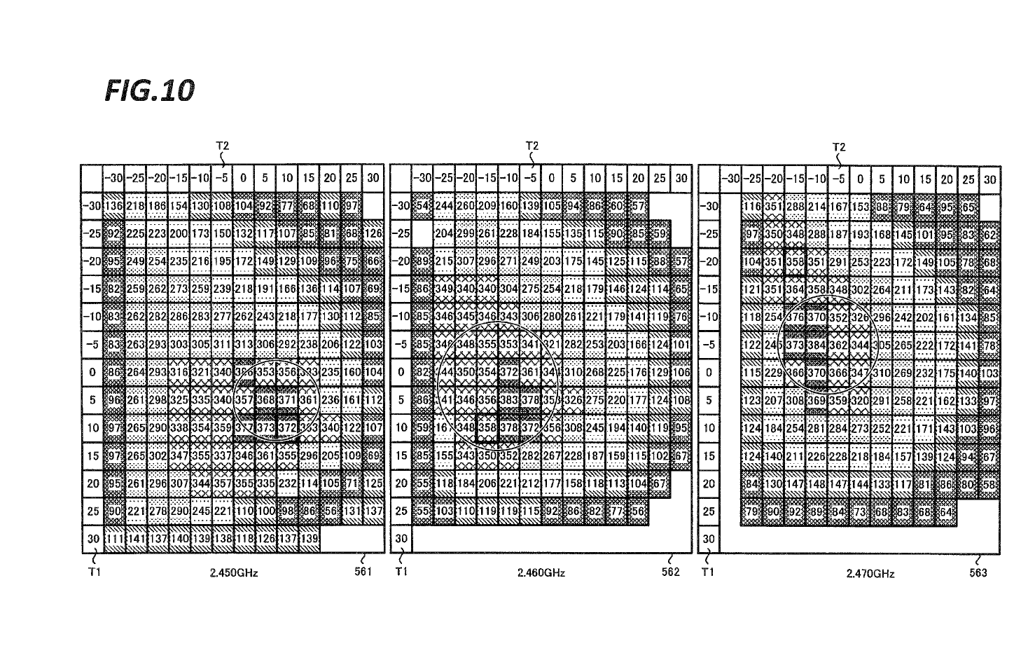

FIG. 10 is a view illustrating a correlation among the oscillated frequency, a light emission intensity of plasma of a specific wavelength inside the processing container, and positions of the movable plates of the tuner. The correlation represented in FIG. 10 is acquired by the correlation acquisition unit 111. In FIG. 10, the diagram 561 represents the correlation when the oscillated frequency is 2.450 GHz, the diagram 562 represents the correlation when the oscillated frequency is 2.460 GHz, and the diagram 563 represents the correlation when the oscillated frequency is 2.470 GHz. In addition, in FIG. 10, T1 indicates the position (mm) of the movable plate 26a of the tuner 26, T2 indicates the position (mm) of the movable plate 26b of the tuner 26, and values surrounded by T1 and T2 indicate the light emission intensity (abu) of plasma of a specific wavelength inside the processing container 12. In addition, in FIG. 10, it is assumed that Ar is used as the processing gas.

As represented in FIG. 10, the range where the light emission intensity of plasma is equal to or more than 340 abu is large when the oscillated frequency is 2.460 GHz, as compared to when the oscillated frequency is 2.450 GHz or 2.470 GHz. That is, when the frequency of the microwaves is 2.460 GHz, Ar is effectively brought into the plasma state, and the positional margin of the movable plates of the tuner is secured so that there is a high possibility that the uniformity of the plasma will be maintained in the plasma-processing step. Thus, the target frequency specifying unit 112 specifies 2.460 GHz as a predetermined target frequency for the plasma-processing step.

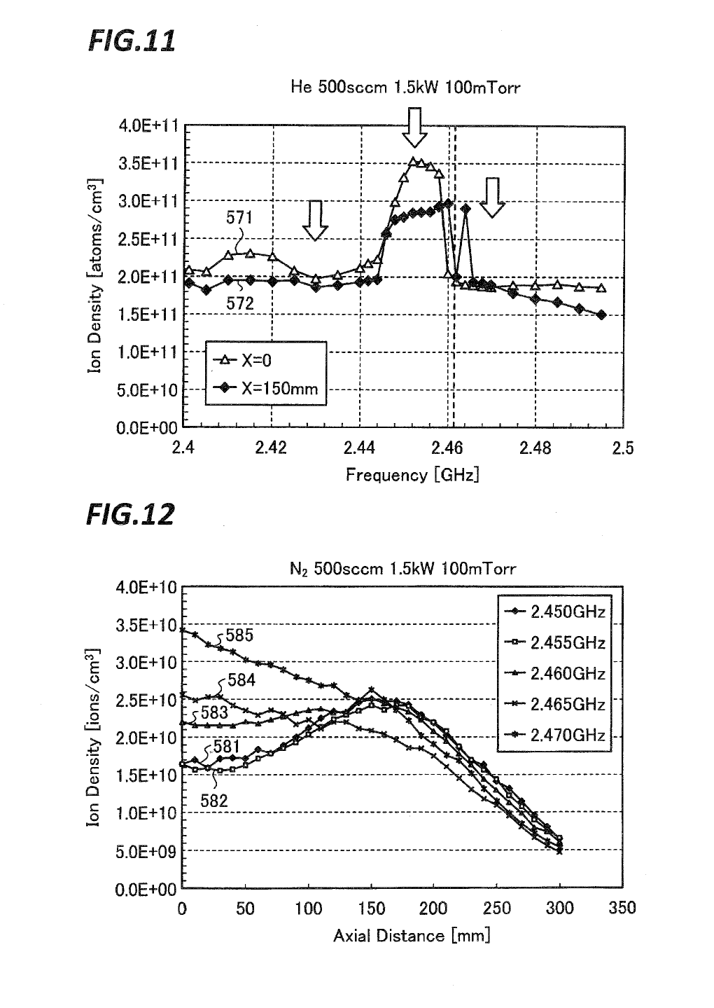

FIG. 11 is a view (1) illustrating a correlation between the oscillated frequency and the plasma density. The correlation represented in FIG. 11 is acquired by the correlation acquisition unit 111. In FIG. 11, the horizontal axis indicates the frequency of the microwaves oscillated by the PLL oscillator 16, i.e., the oscillated frequency (GHz), and the vertical axis indicates an ion density (atoms/cm³) as an example of the plasma density inside the processing container 12.

In FIG. 11, the graph 571 represents a change of the ion density at a position that is 100 mm spaced downward from the bottom surface of the dielectric window 20 and corresponds to the center position of the dummy wafer (hereinafter, referred to as a “center position ion density”). The graph 572 represents a change of the ion density at a position that is 100 mm spaced downward from the bottom surface of the dielectric window 20 and corresponds to the edge position of the dummy wafer (hereinafter, referred to as an “edge position ion density”).

In addition, in FIG. 11, it is assumed that 500 sccm He is used as the processing gas, the power of the traveling waves of the microwaves is 1.5 kW, and the pressure inside the processing chamber 12 is 100 mTorr.

As illustrated in FIG. 11, the center position ion density and the edge position ion density become relatively low when the oscillated frequency is in a range of 2.42 GHz to 2.44 GHz or a range of 2.464 GHz to 2.48 GHz. In other words, when the parameter meets the predetermined condition where the center position ion density and the edge position ion density become equal to or less than a predetermined threshold value (e.g., 2.5E+11 atoms/cm³), the frequency of the microwaves corresponding to the parameter meeting the predetermined condition is in the range of 2.42 GHz to 2.44 GHz or the range of 2.464 GHz to 2.48 GHz. That is, when the frequency of the microwaves is in the range of 2.42 GHz to 2.44 GHz or the range of 2.464 GHz to 2.48 GHz, the plasma density in the plasma-processing step is kept at a relatively low value. Thus, when the plasma density is controlled to be a relatively low value in the plasma-processing step, the target frequency specifying unit 112 selects the frequency of the microwaves from the range of 2.42 GHz to 2.44 GHz or the range of 2.464 GHz to 2.48 GHz, and specifies the selected frequency of the microwaves as a predetermined target frequency for the plasma-processing step.

In addition, as represented in FIG. 11, the center position ion density becomes relatively high when the oscillated frequency is in a range of 2.448 GHz to 2.456 GHz. In other words, when the parameter meets the predetermined condition where the center position ion density becomes a predetermined threshold value (e.g., 3.0E+11 atoms/cm³) or more, the frequency of the microwaves corresponding to the parameter meeting the predetermined condition is in the range of 2.448 GHz to 2.456 GHz. That is, when the frequency of the microwaves is in the range of 2.448 GHz to 2.456 GHz, the plasma density in the plasma-processing step is kept at a relatively high value. Thus, when the plasma density is controlled to be a relatively high value in the plasma-processing step, the target frequency specifying unit 112 selects the frequency of the microwaves from the range of 2.448 GHz to 2.456 GHz, and specifies the selected frequency of microwaves as a predetermined target frequency for the plasma-processing step.

In addition, as represented in FIG. 11, a mode jump occurs as a phenomenon that the ion density is instantaneously discontinuous, when the oscillated frequency is in a range of 2.46 GHz to 2.464 GHz. In other words, when the parameter meets the predetermined condition that no mode jump occurs, the frequency of the microwaves corresponding to the parameter meeting the predetermined condition is in a range other than the range of 2.46 GHz to 2.464 GHz. When the frequency of the microwaves is in a range other than the range of 2.46 GHz to 2.464 GHz, the mode jump does not occur in the plasma-processing step. Thus, the target frequency specifying unit 112 selects the frequency of the microwaves from a range other than the range of 2.46 GHz to 2.464 GHz, and specifies the selected frequency of the microwaves as a predetermined target frequency for the plasma-processing step.

FIG. 12 is a view (2) illustrating a correlation between the oscillated frequency and the plasma density. The correlation represented in FIG. 12 is acquired by the correlation acquisition unit 111. In FIG. 12, the horizontal axis indicates a radial position (mm) of the dummy wafer, and the vertical axis indicates the ion density (atoms/cm³) as an example of the plasma density inside the processing container 12. That is, FIG. 12 represents a distribution of the ion density to the position “300 mm” apart from the center position of the dummy wafer when it is assumed that the center position of the dummy wafer is “0.” In addition, in FIG. 12, it is assumed that a position “150 mm” apart from the center position of the dummy wafer is the edge position of the dummy wafer.

In addition, in FIG. 12, the graph 581 represents the distribution of the ion density when the oscillated frequency is 2.450 GHz. The graph 582 represents the distribution of the ion density when the oscillated frequency is 2.455 GHz. The graph 583 represents the distribution of the ion density when the oscillated frequency is 2.460 GHz. The graph 584 represents the distribution of the ion density when the oscillated frequency is 2.465 GHz. The graph 585 represents the distribution of the ion density when the oscillated frequency is 2.470 GHz.

In addition, in FIG. 12, it is assumed that 500 sccm N₂ is used as the processing gas, the power of the traveling waves of the microwaves is 1.5 kW, and the pressure inside the processing container 12 is 100 mTorr.

As illustrated in FIG. 12, when the oscillated frequency is 2.460 GHz, a difference between the ion density corresponding to the center position of the dummy wafer and the ion density corresponding to the edge position is equal to or less than 5 ions/cm³. In other words, when the parameter meets the predetermined condition that the difference between the ion density corresponding to the center position of the dummy wafer and the ion density corresponding to the edge position is equal to or less than a predetermined threshold value (e.g., 5 ions/cm³), the frequency of the microwaves corresponding to the parameter meeting the predetermined condition is 2.460 GHz. That is, when the frequency of the microwaves is 2.460 GHz, the difference between the ion density corresponding to the center position of the dummy wafer and the ion density corresponding to the edge position is controlled to be equal to or less than 5 ions/cm³ in the plasma-processing step. Thus, when the distribution of the plasma density is controlled to be uniform along the radial direction of the wafer in the plasma-processing step, the target frequency specifying unit 112 specifies 2.460 GHz as a predetermined target frequency for the plasma-processing step.

In addition, as represented in FIG. 12, when the oscillated frequency is 2.450 GHz or 2.455 GHz, the ion density corresponding to the edge position of the dummy wafer increases by 5 ions/cm³ or more, as compared to the ion density corresponding to the center position. In other words, when the parameter meets the predetermined condition that the ion density corresponding to the edge position of the dummy wafer increases by 5 ions/cm³ or more, as compared to the ion density corresponding to the center position, the frequency of the microwaves corresponding to the parameter meeting the predetermined condition is 2.450 GHz or 2.455 GHz. That is, when the frequency of the microwaves is 2.450 GHz or 2.455 GHz, the ion density distribution where the ion density corresponding to the edge position of the dummy wafer is higher than the ion density corresponding to the center position is implemented in the plasma-processing step. Thus, when a control to increase the ion density corresponding to the edge position of the wafer is performed in the plasma-processing step, the target frequency specifying unit 112 specifies 2.450 GHz or 2.455 GHz as a predetermined target frequency for the plasma-processing step.

In addition, as represented in FIG. 12, when the oscillated frequency is 2.465 GHz or 2.470 GHz, the ion density corresponding to the center position of the dummy wafer increases by 5 ion/cm³ or more, as compared to the ion density corresponding to the edge position. In other words, when the parameter meets the predetermined condition that the ion density corresponding to the center position of the dummy wafer increases by 5 ion/cm³ or more, as compared to the ion density corresponding to the edge position, the frequency of the microwaves corresponding to the parameter meeting the predetermined condition is 2.465 GHz or 2.470 GHz. That is, when the frequency of the microwaves is 2.465 GHz or 2.470 GHz, the ion density distribution where the ion density corresponding to the center position of the dummy wafer is higher than the ion density corresponding to the edge position is implemented in the plasma-processing step. Thus, when a control to increase the ion density corresponding to the center position of the wafer is performed in the plasma-processing step, the target frequency specifying unit 112 specifies 2.465 GHz or 2.470 GHz as a predetermined target frequency for the plasma-processing step.

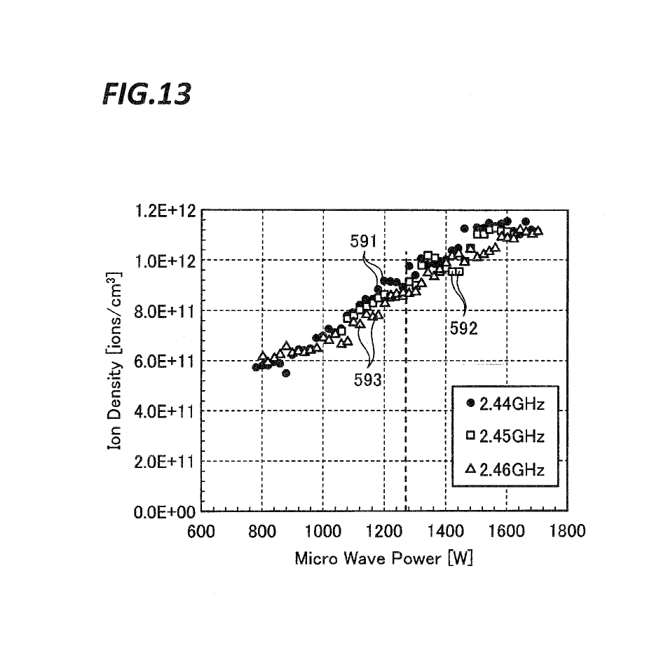

FIG. 13 is a view (3) illustrating a correlation between the oscillated frequency and the plasma density. The correlation represented in FIG. 13 is acquired by the correlation acquisition unit 111. In FIG. 13, the horizontal axis indicates the power (W) of the traveling waves of the microwaves, and the vertical axis indicates the ion density (atoms/cm³) as an example of the plasma density inside the processing container 12.

In addition, in FIG. 13, the circular-shaped point group 591 represents the ion density when the oscillated frequency is 2.44 GHz. The square-shaped point group 592 represents the ion density when the oscillated frequency is 2.45 GHz. The triangle-shaped point group 593 represents the ion density when the oscillated frequency is 2.46 GHz.

As illustrated in FIG. 13, a mode jump may occur as a phenomenon that the ion density is instantaneously discontinuous, depending on a combination of the power of the traveling waves of the microwaves and the oscillated frequency. For example, a case where the power of the traveling waves of the microwaves is set to about 1,280 W is taken into account. Then, the mode jump occurs when the oscillated frequency is 2.44 GHz. In other words, when the power of the traveling waves of the microwaves is set to about 1,280 W, the frequency of the microwaves is set to a frequency (e.g., 2.45 GHz or 2.46 GHz) other than 2.44 GHz so as to avoid the occurrence of the mode jump in the plasma-processing step. Thus, when the power of the traveling waves of the microwaves is set to about 1,280 W, the target frequency specifying unit 112 specifies a frequency (e.g., 2.45 GHz or 2.46 GHz) other than 2.44 GHz as a predetermined target frequency for the plasma-processing step.

Descriptions are continued returning to FIG. 4. When each of the plurality of steps for plasma-processing the workpiece W is performed, the frequency adjustment unit 113 adjusts the frequency of the microwaves oscillated by the PLL oscillator 16 to a predetermined target frequency for each of the steps, at the timing when each of the plurality of steps is switched. Specifically, the frequency adjustment unit 113 adjusts the frequency of the microwaves oscillated by the PLL oscillator 16 to a target frequency specified by the target frequency specifying unit 112, at the timing when each of the plurality of steps is switched. For example, when the igniting step for bringing the processing gas into the plasma state using microwaves is performed, the frequency adjustment unit 113 adjusts the frequency of the microwaves oscillated by the PLL oscillator 16 to a target frequency specified for the igniting step. In addition, for example, when the plasma-processing step for plasma-processing the workpiece W by the plasma of the processing gas is performed, the frequency adjustment unit 113 adjusts the frequency of the microwaves oscillated by the PLL oscillator 16 to a target frequency specified for the plasma-processing step.

In addition, the frequency adjustment unit 113 adjusts the frequency of the microwaves oscillated by the PLL oscillator 16 to be different for each of the steps, at the timing when each of the plurality of steps is switched. For example, a case is taken into account in which the igniting step for bringing the processing gas into the plasma state using microwaves is switched to the plasma-processing step for plasma-processing the workpiece W by the plasma of the processing gas. In this case, the frequency adjustment unit 113 adjusts the frequency of the microwaves to a target frequency corresponding to the plasma-processing step which is different from a target frequency corresponding to the igniting step, at the timing when the igniting step is switched to the plasma-processing step.

In addition, the frequency adjustment unit 113 keeps the frequency of the microwaves oscillated by the PLL oscillator 16 at the target frequency for a time period during which the switched step is performed.

In addition, in the above-described example, the frequency adjustment unit 113 adjusts the frequency of the microwaves oscillated by the PLL oscillator 16 to a target frequency specified by the target frequency specifying unit 112. However, the present disclosure is not limited thereto. For example, when a target frequency is stored in association with each of the plurality of steps in the process recipes stored in the storage unit 103, the frequency adjustment unit 113 adjusts the frequency of the microwaves as follows. That is, the frequency adjustment unit 113 adjusts the frequency of the microwaves oscillated by the PLL oscillator 16 to a target frequency associated with a switching destination step in the process recipes with reference to the process recipes at the timing when each of the plurality of steps is switched.

In addition, in the above-described example, the target frequency is different for each of the steps. However, the present disclosure is not limited thereto. The target frequency may be the same in at least two of the plurality of steps.

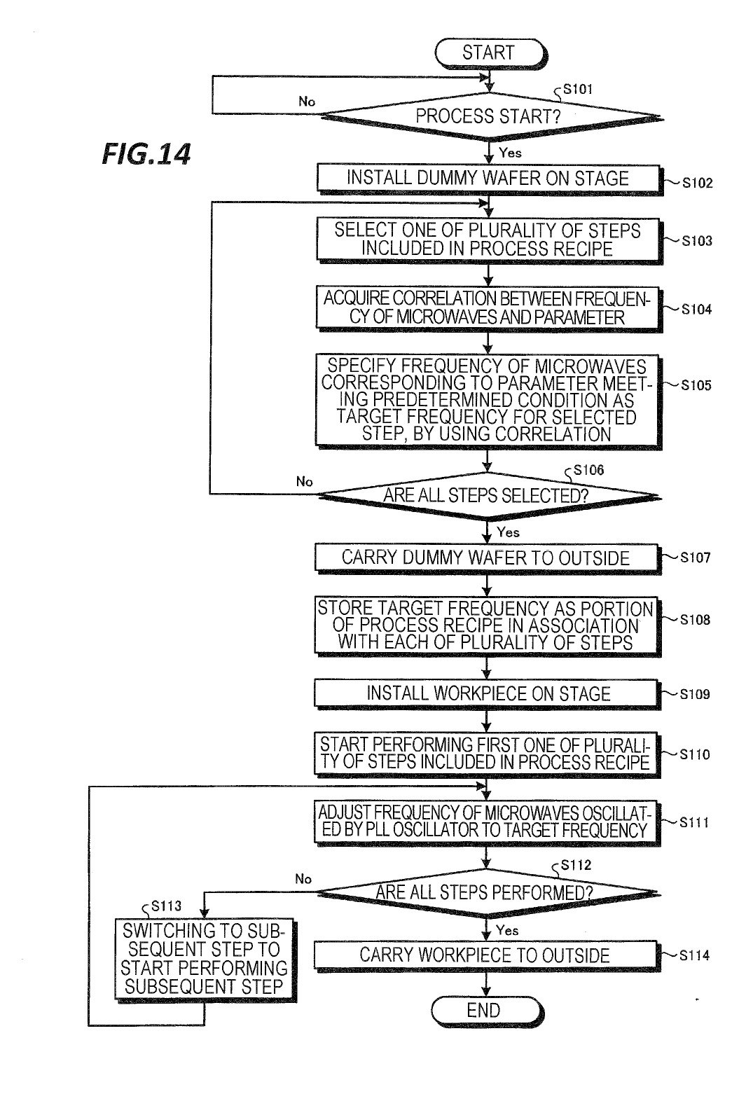

Next, descriptions will be made on an exemplary processing flow of the plasma processing method using the plasma processing apparatus 1 according to an exemplary embodiment. FIG. 14 is a flow chart illustrating an exemplary processing flow of the plasma processing method using the plasma processing apparatus according to an exemplary embodiment.

As illustrated in FIG. 14, when a process start timing comes (S101; Yes), the controller 101 installs the dummy wafer on the stage 14 (S102).

The correlation acquisition unit 111 of the controller 101 selects one of the plurality of steps included in the process recipes with reference to the process recipes stored in the storage unit 103 (S103). The correlation acquisition unit 111 acquires a correlation between the frequency of the microwaves oscillated by the PLL oscillator 16 and a predetermined parameter to be applied to the selected step, in the state where the dummy wafer is placed on the stage 14 (S104).

Subsequently, the target frequency specifying unit 112 specifies the frequency of the microwaves corresponding to the parameter meeting a predetermined condition, as a target frequency for the selected step (S105).

When any of the steps included in the process recipes is not selected (S106; No), the correlation acquisition unit 111 returns the process to S103. Meanwhile, when all the steps included in the process recipes are selected (S106; Yes), the correlation acquisition unit 111 carries the dummy wafer to the outside of the processing container 12 (S107).

Subsequently, the target frequency specifying unit 112 stores the target frequency as a portion of the process recipes in association with each of the plurality of steps included in the process recipes, in the storage unit 103 (S108).

Subsequently, the controller 101 installs the workpiece W on the stage 14 (S109), and starts performing the first one of the plurality of steps included in the process recipes with reference to the process recipes stored in the storage unit 103 (S110).

Subsequently, the frequency adjustment unit 113 of the controller 101 adjusts the frequency of the microwaves oscillated by the PLL oscillator 16 to a target frequency for the step to be started (S111).

Subsequently, when any of the steps is not selected (S112: No), the controller 101 switches the step, which is being performed, to a subsequent step, and starts performing the switching destination step (S113) to return the process to S111. At S111, the frequency adjustment unit 113 adjusts the frequency of the microwaves oscillated by the PLL oscillator 16 to a target frequency corresponding to the switching destination step in the process recipes.

Meanwhile, when all the steps are performed (S112: Yes), the controller 101 carries the workpiece W to the outside of the processing container 12 (S114) and ends the process.

As described above, when each of the plurality of steps for plasma-processing the workpiece W is performed, the plasma processing apparatus 1 of an exemplary embodiment adjusts the frequency of the microwaves to a predetermined target frequency for each of the steps at the timing when each of the plurality of steps is switched. For example, when the igniting step is performed, the plasma processing apparatus 1 adjusts the frequency of the microwaves to a target frequency at which the processing gas is sufficiently brought into the plasma state. In addition, for example, when the plasma-processing step is performed, the plasma processing apparatus 1 adjusts the frequency of the microwaves to a target frequency at which the uniformity of the plasma is maintained. As a result, according to the plasma processing apparatus 1 of an exemplary embodiment, when each of the plurality of steps for plasma-processing the workpiece is performed, the frequency of the microwaves may be adjusted to an optimum frequency for each of the steps.

Further, according to the plasma processing apparatus 1 of an exemplary embodiment, the following secondary effects may also be obtained. That is, since the frequency at which plasma is most prone to be ignited may be set in the plasma igniting step, the ignition may be performed with a less power so that the consumption of an electrode member and the generation of particles may be suppressed. Further, since a change of a condition is not required between the igniting step and the process step, and the process step is ended only with the change of the frequency so that the process time is largely reduced. Further, since an optimum frequency different depending on gas types and conditions is set in the process step, the microwaves are effectively absorbed to plasma, and as a result, the plasma density is high so that the plasma becomes stable, and the in-plane uniformity of the plasma density is high so that it is possible to provide a plasma processing method in which a difference in process condition for respective apparatuses is small. By setting a frequency avoiding a frequency region where a so-called mode jump in which the plasma state changes occurs, plasma with a large stable margin may be provided.

In addition, the plasma processing apparatus 1 of an exemplary embodiment acquires a correlation between the frequency of the microwaves and a predetermined parameter to be applied to each of the plurality of steps in the state where the dummy wafer is placed on the stage 14, before the plurality of steps is performed. Then, the plasma processing apparatus 1 specifies the frequency of the microwaves corresponding to the parameter meeting a predetermined condition as a target frequency, by using the correlation. Then, when each of the plurality of steps is performed, the plasma processing apparatus 1 adjusts the frequency of the microwaves to the target frequency specified by using the correlation at the timing when each of the plurality of steps is switched. As a result, according to the plasma processing apparatus 1 of an exemplary embodiment, an optimum frequency of microwaves may be automatically specified for each step before the plurality of steps is performed.

### Other Embodiments

Although the plasma processing apparatus 1 of an exemplary embodiment has been described, the present disclosure is not limited thereto. Hereinafter, other embodiments will be described.

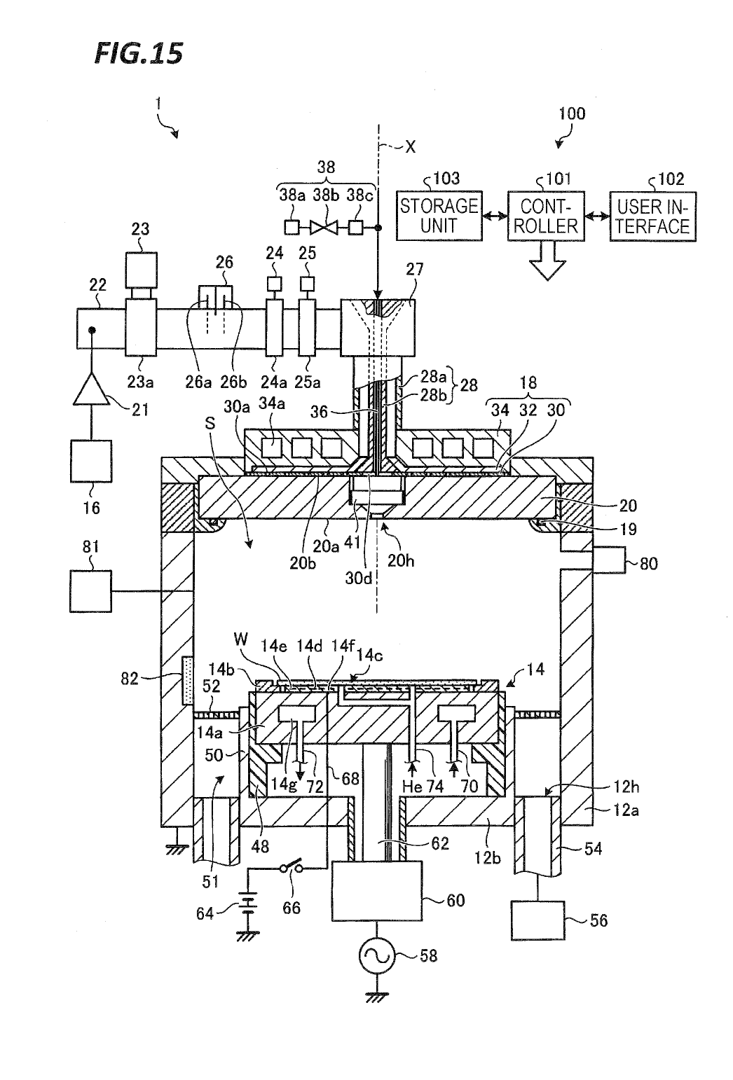

For example, as illustrated in FIG. 15, in the plasma processing apparatus 1, the placement position of the detector 24 and the detector 25 and the placement position of the tuner 26 may be exchanged with each other. In addition, FIG. 15 is a view illustrating an exemplary configuration of a plasma processing apparatus according to another exemplary embodiment.

In addition, in the above-described embodiment, the example where the microwaves are guided by the waveguide 22 has been described. However, the present disclosure is not limited thereto. For example, the microwaves may be guided by using a coaxial cable, instead of the waveguide 22.

### DESCRIPTION OF SYMBOL

1: plasma processing apparatus

12: processing container

14: stage

16: PLL oscillator

18: antenna

20: dielectric window

30: slot plate

38: gas supply system

80: spectroscopic sensor

81: vacuum gauge

82: plasma distribution imaging camera

100: control unit

101: controller

102: user interface

103: storage unit

111: correlation acquisition unit

112: target frequency specifying unit

113: frequency adjustment unit

1. A plasma processing apparatus comprising:
a processing container;
a placing table provided inside the processing container and configured to place a workpiece thereon;
a gas supply mechanism configured to supply a processing gas used for a plasma reaction into the inside of the processing container;
a plasma generating mechanism including a microwave oscillator, and configured to bring the processing gas supplied to the inside of the processing container into a plasma state using microwaves oscillated by the microwave oscillator; and
an adjustment unit configured to adjust, when each of a plurality of steps for plasma-processing the workpiece is performed, a frequency of the microwaves oscillated by the microwave oscillator to a predetermined target frequency for each of the steps, at a timing when each of the plurality of steps is switched.

2. The plasma processing apparatus of claim 1, wherein the adjustment unit adjusts the frequency of the microwaves oscillated by the microwave oscillator to the target frequency different for each of the steps, at the timing when each of the plurality of steps is switched.

3. The plasma processing apparatus of claim 1, wherein the adjustment unit keeps the frequency of the microwaves oscillated by the microwave oscillator at the target frequency for a time period during which a switched step is performed.

4. The plasma processing apparatus of claim 1, wherein the target frequency is stored in association with each of the plurality of steps in a process recipe for performing a process, and the adjustment unit adjusts the frequency of the microwaves oscillated by the microwave oscillator to the target frequency associated with a switching destination step in the process recipe with reference to the process recipe at the timing when each of the plurality of steps is switched.

5. The plasma processing apparatus of claim 1, further comprising:
an acquisition unit configured to acquire a correlation between the frequency of the microwaves oscillated by the microwave oscillator and a predetermined parameter to be applied to each of the plurality of steps, in a state where a separate workpiece from the workpiece is placed on the placing table before the plurality of steps is performed; and
a specifying unit configured to specify the frequency of the microwaves corresponding to a parameter meeting a predetermined condition as the target frequency, by using the correlation acquired by the acquisition unit,
wherein, when each of the plurality of steps is performed, the adjustment unit adjusts the frequency of the microwaves oscillated by the microwave oscillator to the target frequency specified by the specifying unit at the timing when each of the plurality of steps is switched.

6. The plasma processing apparatus of claim 5, wherein the parameter is at least one of: (1) a light emission intensity of plasma of a specific wavelength inside the processing container, (2) a variation of the light emission intensity per unit time, (3) a position of a movable plate provided in a tuner to match impedances between the microwave oscillator and the processing container, (4) a power of traveling waves of the microwaves, (5) a power of reflected waves of the microwaves, (6) a pixel value indicating a plasma distribution obtained by an image processing, (7) a pressure inside the processing container, (8) a flow rate of the processing gas, (9) a bias power, and (10) a plasma density inside the processing container.

7. A plasma processing method using a plasma processing apparatus including: a processing container; a placing table provided inside the processing container and configured to place a workpiece thereon; a gas supply mechanism configured to supply a processing gas used for a plasma reaction to the inside of the processing container; and a plasma generating mechanism including a microwave oscillator and configured to bring the processing gas supplied to the inside of the processing container into a plasma state using microwaves oscillated by the microwave oscillator,
wherein, when each of a plurality of steps for plasma-processing the workpiece is performed, a frequency of the microwaves oscillated by the microwave oscillator is adjusted to a predetermined target frequency for each of the steps, at a timing when each of the plurality of steps is switched.
